(19) United States
(12) Patent Application Publication
(10) Pub. No.: US 2017/0114455 A1
(43) Pub. Date: Apr. 27, 2017

(54) THERMALLY CONDUCTIVE COMPOSITION WITH CERAMIC-COATED ELECTRICALLY CONDUCTIVE FILLER

(71) Applicant: Jones Tech (USA), Inc., Cupertino, CA (US)

(72) Inventor: Xiaoning Wu, Beijing (CN)

(21) Appl. No.: 14/923,239

(22) Filed: Oct. 26, 2015

(51) Int. Cl. C23C 16/44; C09K 5/14

(52) U.S. Cl. CPC C23C 16/44; C09K 5/14

(57) ABSTRACT

A thermally conductive composition having an electrically conductive filler with a ceramic coating selected to provide a relatively high dielectric breakdown voltage of the thermally conductive composition while maintaining a relatively high thermal conductivity of the thermally conductive composition.

### BACKGROUND

A thermally conductive composition can include an electrically conductive filler. An electrically conductive filler can increase the thermal conductivity of the thermally conductive composition. An electrically conductive filler can also decrease the dielectric breakdown voltage of the thermally conductive composition.

A decrease in the dielectric breakdown voltage of a thermally conductive composition can cause failures. For example, a relatively low dielectric breakdown voltage of a thermally conductive composition that couples a heat-generating component of an electronics device to a heat-dissipating structure can cause an electrical short circuit in the electronics device.

### SUMMARY

In general, in one aspect, the invention relates to a thermally conductive composition having an electrically conductive filler with a ceramic coating selected to maintain a relatively high dielectric breakdown voltage of the thermally conductive composition while maintaining a relatively high thermal conductivity of the thermally conductive composition.

In general, in another aspect, the invention relates to a method for forming a thermally conductive composition. The method can include: forming a ceramic coating on an electrically conductive filler for the thermally conductive composition; and mixing the thermally conductive composition including the electrically conductive filler with the ceramic coating such that the ceramic coating provides a relatively high dielectric breakdown voltage of the thermally conductive composition while maintaining a relatively high thermal conductivity of the thermally conductive composition.

Other aspects of the invention will be apparent from the following description and the appended claims.

### BRIEF DESCRIPTION OF THE DRAWINGS

Embodiments of the present invention are illustrated by way of example, and not by way of limitation, in the figures of the accompanying drawings and in which like reference numerals refer to similar elements.

FIG. 1 illustrates a thermally conductive composition in one or more embodiments.

FIG. 2 shows a thermally conductive composition thermally coupling a heat-generating component to a heat-dissipating structure.

FIG. 3 illustrates a method for forming a thermally conductive composition in one or more embodiments.

### DETAILED DESCRIPTION

Reference will now be made in detail to the various embodiments of the present disclosure, examples of which are illustrated in the accompanying drawings. Like elements in the various figures are denoted by like reference numerals for consistency. While described in conjunction with these embodiments, it will be understood that they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, have not been described in detail so as not to unnecessarily obscure aspects of the present disclosure.

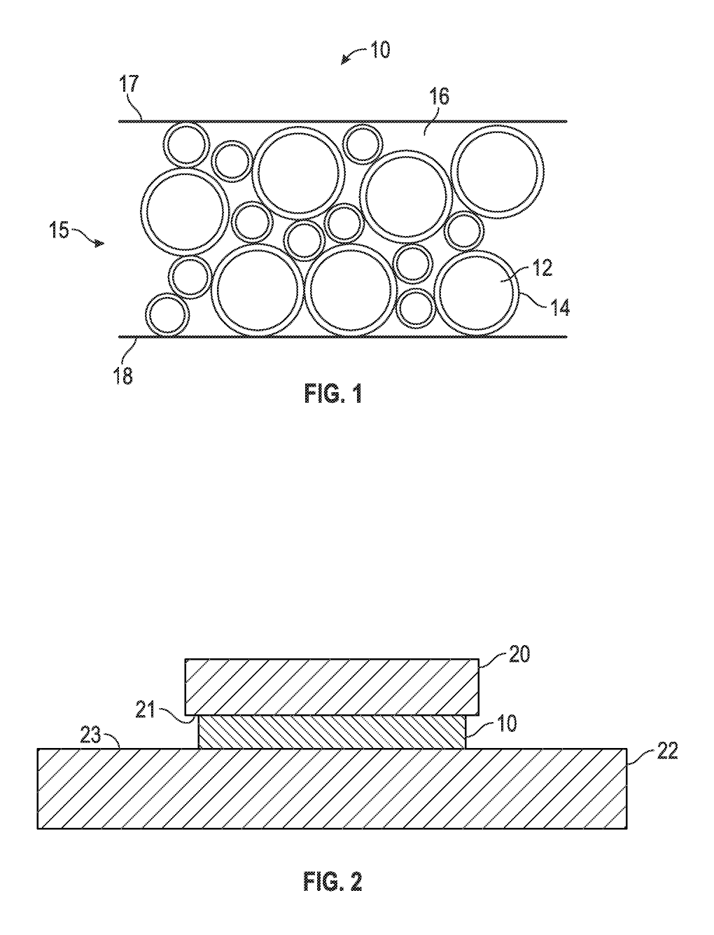

FIG. 1 illustrates a thermally conductive composition 10 in one or more embodiments. The thermally conductive composition 10 includes an electrically conductive filler 12 with a ceramic coating 14 selected to provide a relatively high dielectric breakdown voltage of the thermally conductive composition 10 while maintaining a relatively high thermal conductivity of the thermally conductive composition 10.

In one or more embodiments, a thickness of the ceramic coating 14 is controlled to provide the relatively high dielectric breakdown voltage of the thermally conductive composition 10. The thickness of the ceramic coating 14 can be varied to vary the dielectric breakdown voltage of the thermally conductive composition 10.

In one or more embodiments, the thickness of the ceramic coating 14 is controlled to maintain the relatively high thermal conductivity of the thermally conductive composition 10. The thickness of the ceramic coating 14 can be varied to vary the thermal conductivity of the thermally conductive composition 10.

In one or more embodiments, the thickness of the ceramic coating 14 is controlled in response to a desired balance between the relatively high dielectric breakdown voltage and the relatively high thermal conductivity of the thermally conductive composition 10. For example, the thickness of the ceramic coating 14 can be increased to increase the dielectric breakdown voltage of the thermally conductive composition 10 at the expense of some of the thermal conductivity of the thermally conductive composition 10. Conversely, the thickness of the ceramic coating 14 can be decreased to increase the thermal conductivity of the thermally conductive composition 10 at the expense of some of the dielectric breakdown voltage margin of the thermally conductive composition 10.

In one or more embodiments, the electrically conductive filler 12 a metal. Example metals for the electrically conductive filler 12 include aluminum, copper, and silver.

In one or more embodiments, the electrically conductive filler 12 is an electrically conductive non-metal material. Example non-metals for the electrically conductive filler 12 include carbon fiber, carbon nanotube, and graphite.

In one or more embodiments, the ceramic coating 14 is formed on a surface of the electrically conductive filler 12 using a chemical vapor deposition (CVD) process. Examples of the ceramic coating 14 include an aluminum oxide coating, a silica coating, and a zinc oxide coating.

In one or more embodiments, the electrically conductive filler 12 is mixed in a layer 15 with a polymer resin 16. Examples of the polymer resin 16 include silicone rubber, epoxy, polyurethane, and polyacrylate.

The thickness of the ceramic coating 14 in one or more embodiments can range between 0.1 micrometers and 20 micrometers. The preferred range of the thickness of the ceramic coating 14 in one or more embodiments can be between 0.5 micrometers and 5 micrometers.

In one example embodiment of the thermally conductive composition 10, the electrically conductive filler 12 is aluminum and the ceramic coating 14 is a 3-micrometer thick layer of aluminum oxide. The aluminum oxide layer can be prepared through a fluidized bed chemical vapor deposition (FBCVD) process using aluminum acetylacetonate as precursor.

The thickness of the ceramic coating 14 can be controlled by controlling one or more of the FBCVD process parameters. The FBCVD process parameters that can be controlled can include bed temperature, carrier gas flow rate sent through the vaporizer line, and coating duration.

In one or more embodiments, the thickness of the ceramic coating 14 is selected so that it yields a relatively high thermal conductivity between a surface 17, the intervening mixture of the polymer resin 16 and the electrically conductive filler 12 with the ceramic coating 14, and a surface 18 of the thermally conductive composition 10 while maintaining a relatively high dielectric breakdown voltage across the thermally conductive composition 10 between the surfaces 17 and 18.

FIG. 2 shows the thermally conductive composition 10 thermally coupling a heat-generating component 20 to a heat-dissipating structure 22. For example, the heat-generating component 20 can be an integrated circuit chip mounted on a printed circuit board and the heat-dissipating structure 22 can be a heat sink for the components of the printed circuit board.

A surface 21 of the heat-generating component 20 thermally couples to the surface 17 (FIG. 1) of the thermally conductive composition 10. A surface 23 of the heat-dissipating structure 22 thermally couples to the surface 18 (FIG. 1) of the thermally conductive composition 10. The thickness of the ceramic coating 14 (FIG. 1) in the thermally conductive composition 10 is selected so that the thermally conductive composition 10 provides a relatively high thermal conductivity path between the heat-generating component 20 and the heat-dissipating structure 22 while maintaining a relatively high dielectric breakdown voltage between the heat-generating component 20 and the heat-dissipating structure 22.

The relatively high dielectric breakdown voltage between the heat-generating component 20 and the heat-dissipating structure 22 avoids damage to and failure of the thermally conductive composition 10 when a relatively large voltage differential exists between the heat-generating component 20 and the heat-dissipating structure 22. In one or more embodiments, the thermally conductive composition 10 provides a dielectric breakdown voltage above 5 kilovolts per millimeter while also providing a thermal conductivity of up to 8 watts per meter-kelvin.

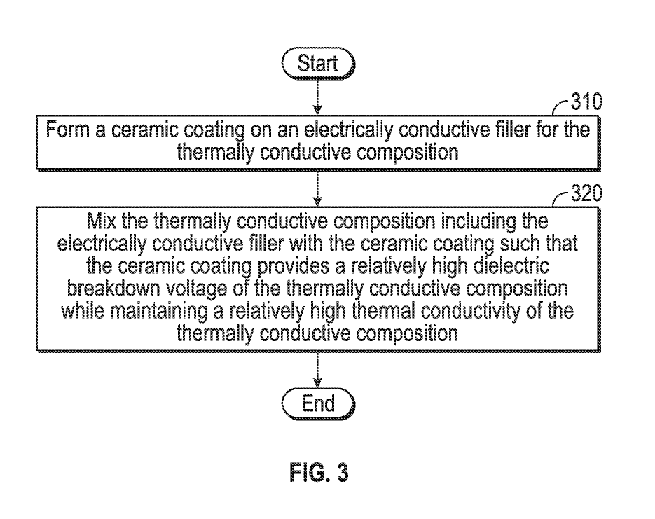

FIG. 3 illustrates a method for forming a thermally conductive composition in one or more embodiments. While the various steps in this flowchart are presented and described sequentially, one of ordinary skill will appreciate that some or all of the steps can be executed in different orders and some or all of the steps can be executed in parallel. Further, in one or more embodiments, one or more of the steps described below can be omitted, repeated, and/or performed in a different order. Accordingly, the specific arrangement of steps shown in FIG. 3 should not be construed as limiting the scope of the invention.

At step 310, a ceramic coating is formed on an electrically conductive filler for the thermally conductive composition. The ceramic coating can be formed by a CVD process.

At step 320, the thermally conductive composition including the electrically conductive filler with the ceramic coating is mixed such that the ceramic coating provides a relatively high dielectric breakdown voltage of the thermally conductive composition while maintaining a relatively high thermal conductivity of the thermally conductive composition. The electrically conductive filler with the ceramic coating can be mixed in a polymer resin.

The CVD precursors and parameters can be controlled to control the thickness of the ceramic coating in response to a desired dielectric breakdown voltage of the thermally conductive composition. The CVD precursors and parameters can be controlled to control the thickness of the ceramic coating in response to a desired thermal conductivity of the thermally conductive composition. The CVD precursors and parameters can be controlled to control the thickness of the ceramic coating in response to a desired balance between the dielectric breakdown voltage and the thermal conductivity of the thermally conductive composition.

While the foregoing disclosure sets forth various embodiments using specific diagrams, flowcharts, and examples, each diagram component, flowchart step, operation, and/or component described and/or illustrated herein may be implemented, individually and/or collectively, using a range of processes and components.

The process parameters and sequence of steps described and/or illustrated herein are given by way of example only. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

While the invention has been described with respect to a limited number of embodiments, those skilled in the art, having benefit of this disclosure, will appreciate that other embodiments may be devised which do not depart from the scope of the invention as disclosed herein.

What is claimed is:

1. A thermally conductive composition having an electrically conductive filler with a ceramic coating selected to provide a relatively high dielectric breakdown voltage of the thermally conductive composition while maintaining a relatively high thermal conductivity of the thermally conductive composition.

2. The thermally conductive composition of claim 1, wherein the ceramic coating has a thickness selected to provide the relatively high dielectric breakdown voltage.

3. The thermally conductive composition of claim 1, wherein the ceramic coating has a thickness selected to maintain the relatively high thermal conductivity of the thermally conductive composition.

4. The thermally conductive composition of claim 1, wherein the ceramic coating has a thickness selected in response to a desired balance between the relatively high dielectric breakdown voltage and the relatively high thermal conductivity of the thermally conductive composition.

5. The thermally conductive composition of claim 1, wherein the electrically conductive filler comprises a metal.

6. The thermally conductive composition of claim 1, wherein the electrically conductive filler comprises a carbon fiber.

7. The thermally conductive composition of claim 1, wherein the electrically conductive filler comprises a carbon nanotube.

8. The thermally conductive composition of claim 1, wherein the electrically conductive filler comprises a graphite material.

9. The thermally conductive composition of claim 1, wherein the ceramic coating comprises an aluminum oxide coating.

10. The thermally conductive composition of claim 1, wherein the ceramic coating comprises a silica coating.

11. The thermally conductive composition of claim 1, wherein the ceramic coating comprises a zinc oxide coating.

12. A method for forming a thermally conductive composition, comprising:
forming a ceramic coating on an electrically conductive filler for the thermally conductive composition; and
mixing the thermally conductive composition including the electrically conductive filler with the ceramic coating such that the ceramic coating provides a relatively high dielectric breakdown voltage of the thermally conductive composition while maintaining a relatively high thermal conductivity of the thermally conductive composition.

13. The method of claim 12, wherein forming a ceramic coating comprises forming the ceramic coating using a chemical vapor deposition process.

14. The method of claim 12, wherein forming a ceramic coating comprises forming the ceramic coating with a thickness selected to provide the relatively high dielectric breakdown voltage.

15. The method of claim 12, wherein forming a ceramic coating comprises forming the ceramic coating with a thickness selected to maintain the relatively high thermal conductivity of the thermally conductive composition.

16. The method of claim 12, wherein forming a ceramic coating comprises forming the ceramic coating with a thickness selected in response to a desired balance between the relatively high dielectric breakdown voltage and the relatively high thermal conductivity of the thermally conductive composition.

17. The method of claim 12, wherein forming a ceramic coating comprises forming an aluminum oxide coating.

18. The method of claim 12, wherein forming a ceramic coating comprises forming a silica coating.

19. The method of claim 12, wherein forming a ceramic coating comprises forming a zinc oxide coating.
